(19) United States
(12) Patent Application Publication
(10) Pub. No.: US 2025/0221111 A1
(43) Pub. Date: Jul. 3, 2025

(54) LIGHT-EMITTING DIODE DISPLAY DEVICE AND METHOD OF MANUFACTURING THE SAME

(71) Applicant: LG Display Co., Ltd., Seoul (KR)

(72) Inventor: Ju-Hee JUNG, Paju-si (KR)

(73) Assignee: LG Display Co., Ltd., Seoul (KR)

(21) Appl. No.: 18/927,231

(22) Filed: Oct. 25, 2024

(30) Foreign Application Priority Data
Dec. 28, 2023 (KR) 10-2023-0194835

(51) Int. Cl. H01L 33/48; H01L 25/16; H01L 33/62

(52) U.S. Cl. CPC H10H 20/8506; H01L 25/167; H10H 20/857; H10H 20/0364

(57) ABSTRACT

A light-emitting diode display device and method of manufacturing the same are provided. The light-emitting diode display device includes a substrate; a first electrode over the substrate; a first bank layer on the first electrode and having a first opening exposing the first electrode; an adhesive layer including a first portion on the first electrode exposed through the first opening; and a light-emitting element provided on the first portion of the adhesive layer, wherein the first portion has a side surface provided with a plurality of unevenness.

### CROSS-REFERENCE TO RELATED APPLICATION

The present application claims priority to Korean Patent Application No. 10-2023-0194835 filed in the Republic of Korea on Dec. 28, 2023, the entire contents of which are hereby expressly incorporated by reference into the present application.

### BACKGROUND

### Technical Field

The present disclosure relates to a display device, and more particularly, to a light-emitting diode display device and a method of manufacturing the same.

### Discussion of the Related Art

As the information society progresses, a demand for different types of display devices increases, and flat panel display devices (FPD) such as liquid crystal display devices (LCD) and light-emitting diode (LED) display devices have been developed and applied to various fields.

Among the flat panel display devices, light-emitting diode display devices emit light due to the radiative recombination of an exciton. The exciton is formed from an electron and a hole by injecting charges into a light-emitting layer between a cathode for injecting electrons and an anode for injecting holes in a light-emitting diode.

The light-emitting diode display device has wide viewing angles as compared with a liquid crystal display device because it is self-luminous and also has advantages of a thin thickness, light weight and low power consumption since a backlight unit is not necessary.

The light-emitting diode display device may include inorganic-based light-emitting elements and organic-based light-emitting elements. The inorganic-based light-emitting elements have relatively excellent stability, fast response characteristics, and high contrast ratios, and micro light-emitting diodes (micro LEDs or uLED) are widely used as the inorganic-based light-emitting elements for high resolution.

The inorganic-based light-emitting elements are separately provided on an element substrate and are transferred to a substrate of a display device. Since a pitch of light-emitting elements on the element substrate is different from a pitch of light-emitting elements on the substrate of the display device, in order to transfer the light-emitting elements of the elements substrate onto the substrate of the display device, complex transfer steps are required.

In addition, during the transfer process, the light-emitting elements may be damaged, tilted, or flipped due to impacts, thereby causing a transfer failure.

### SUMMARY

Accordingly, embodiments of the present disclosure are directed to a light-emitting diode display device and a method of manufacturing the same that substantially obviate one or more of the problems due to limitations and disadvantages of the related art.

An aspect of the present disclosure is to provide a light-emitting diode display device capable of preventing a transfer failure of light-emitting elements and a method of manufacturing the same.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, as well as the appended drawings.

To achieve these and other aspects of the inventive concepts, as embodied and broadly described herein, a light-emitting diode display device comprises a substrate; a first electrode over the substrate; a first bank layer on the first electrode and having a first opening exposing the first electrode; an adhesive layer including a first portion on the first electrode exposed through the first opening; and a light-emitting element provided on the first portion of the adhesive layer, wherein the first portion has a side surface provided with a plurality of unevenness.

In another aspect, a method of manufacturing a light-emitting diode display device comprises forming a first electrode over a first substrate; forming a first bank layer on the first electrode and having a first opening exposing the first electrode; forming an adhesive layer on the first bank layer; and transferring a light-emitting element on the adhesive layer corresponding to the first electrode, wherein the adhesive layer includes a first portion between the first electrode and the light-emitting element and a second portion on the first bank layer, and wherein the first portion is separated from the second portion, and the first portion and the second portion each has a side surface provided with a plurality of unevenness.

It is to be understood that both the foregoing general description and the following detailed description are examples and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate aspects of the disclosure and together with the description serve to explain various principles of the disclosure. In the drawings:

FIG. 1 is an equivalent circuit diagram for a sub-pixel of a light-emitting diode display device according to an embodiment of the present disclosure;

FIG. 2 is a schematic plan view of a light-emitting diode display device according to the embodiment of the present disclosure;

FIG. 3 is a schematic cross-sectional view of a light-emitting diode display device according to a first embodiment of the present disclosure;

FIG. 4 is a schematic cross-sectional view of a light-emitting diode display device according to a second embodiment of the present disclosure;

FIG. 5 is a schematic cross-sectional view of a light-emitting diode display device according to a third embodiment of the present disclosure; and

FIGS. 6A to 6K are schematic cross-sectional views of a light-emitting diode display device in steps of manufacturing the same according to the third embodiment of the present disclosure.

### DETAILED DESCRIPTION

Advantages and features of the present disclosure and methods for achieving them will be made clear from embodiments described in detail below with reference to the accompanying drawings. The present disclosure can, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains.

Shapes, sizes, ratios, angles, numbers, and the like disclosed in the drawings for describing the embodiments of the present disclosure are illustrative, and thus the present disclosure is not limited to the illustrated matters. The same reference numerals refer to the same components throughout this disclosure.

Further, in the following description of the present disclosure, when a detailed description of a known related art is determined to unnecessarily obscure the gist of the present disclosure, the detailed description thereof will be omitted herein or may be briefly discussed.

When terms such as “including,” “having,” “comprising” and the like mentioned in this disclosure are used, other parts can be added unless the term “only” is used herein.

Further, when a component is expressed as being singular, being plural is included unless otherwise specified.

In analyzing a component, an error range is interpreted as being included even when there is no explicit description.

In describing a positional relationship, for example, when a positional relationship of two parts/layers is described as being “over,” “on,” “above,” “below,” “under,” “next to,” or the like, one or more other parts/layers can be provided between the two parts/layers, unless the term “immediately” or “directly” is used therewith.

In describing a temporal relationship, for example, when a temporal predecessor relationship is described as being “after,” “subsequent,” “next to,” “prior to,” or the like, unless “immediately” or “directly” is used, cases that are not continuous or sequential can also be included.

Although the terms first, second, and the like are used to describe various components, these components are not substantially limited by these terms. These terms are used only to distinguish one component from another component, and may not define any order or sequence. Therefore, a first component described below can substantially be a second component within the technical spirit of the present disclosure.

Hereinafter, exemplary embodiments of the present disclosure will be described in detail with reference to accompanying drawings.

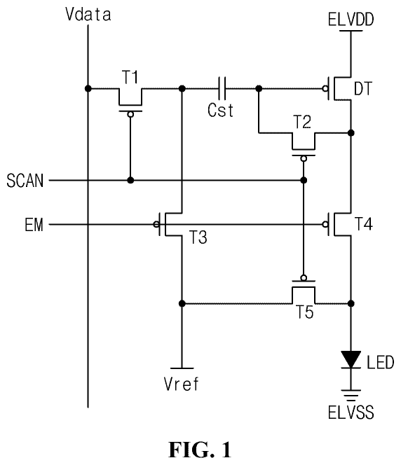

FIG. 1 is an equivalent circuit diagram for a sub-pixel of a light-emitting diode display device according to the embodiment of the present disclosure.

In FIG. 1, one sub-pixel of the light-emitting diode display device according to the embodiment of the present disclosure may include a driving transistor DT, first, second, third, fourth, and fifth transistors T1, T2, T3, T4, and T5, a storage capacitor Cst, and a light-emitting diode LED.

For example, the driving transistor DT and the first, second, third, fourth, and fifth transistors T1, T2, T3, T4, and T5 may be P-type transistors. However, embodiments of the present disclosure are not limited thereto. In other embodiments, the driving transistor DT and the first, second, third, fourth, and fifth transistors T1, T2, T3, T4, and T5 may be N-type transistors.

The driving transistor DT may be switched according to a voltage of a first capacitor electrode of the storage capacitor Cst and may be connected to a high potential voltage ELVDD. Specifically, a gate of the driving transistor DT may be connected to the first capacitor electrode of the storage capacitor Cst and a source of the second transistor T2. A source of the driving transistor DT may be connected to the high potential voltage ELVDD. A drain of the driving transistor DT may be connected to a drain of the second transistor T2 and a source of the fourth transistor T4.

The first transistor T1 may be switched according to a gate signal SCAN and may be connected to a data signal Vdata. Specifically, a gate of the first transistor T1 may be connected to the gate signal SCAN. A source of the first transistor T1 may be connected to the data signal Vdata. A drain of the first transistor T1 may be connected to a second capacitor electrode of the storage capacitor Cst and a source of the third transistor T3.

The second transistor T2 may be switched according to the gate signal SCAN and may be connected to the driving transistor DT. Specifically, a gate of the second transistor T2 may be connected to the gate signal SCAN. The source of the second transistor T2 may be connected to the first capacitor electrode of the storage capacitor Cst and the gate of the driving transistor DT. The drain of the second transistor T2 may be connected to the drain of the driving transistor DT and the source of the fourth transistor T4.

The third transistor T3 may be switched according to an emission signal EM and may be connected to a reference voltage Vref. A gate of the third transistor T3 may be connected to the emission signal EM. The source of the third transistor T3 may be connected to the second capacitor electrode of the storage capacitor Cst and the drain of the first transistor T1. A drain of the third transistor T3 may be connected to the reference voltage Vref and a source of the fifth transistor T5.

The fourth transistor T4 may be switched according to the emission signal EM and may be connected to the driving transistor DT and the light-emitting diode LED. Specifically, a gate of the fourth transistor T4 may be connected to the emission signal EM. The source of the fourth transistor T4 may be connected to the drain of the driving transistor DT and the drain of the second transistor T2. A drain of the fourth transistor T4 may be connected to a drain of the fifth transistor T5 and a first electrode of the light-emitting diode LED.

The fifth transistor T5 may be switched according to the gate signal SCAN and may be connected to the reference voltage Vref and the fourth transistor T4. Specifically, a gate of the fifth transistor T5 may be connected to the gate signal SCAN. The source of the fifth transistor T5 may be connected to the reference voltage Vref and the drain of the third transistor T3. The drain of the fifth transistor T5 may be connected to the drain of the fourth transistor T4 and the first electrode of the light-emitting diode LED.

The storage capacitor Cst may store the data signal Vdata and a threshold voltage Vth of the driving transistor DT. The first capacitor electrode of the storage capacitor Cst may be connected to the gate of the driving transistor DT and the source of the second transistor T2. The second capacitor electrode of the storage capacitor Cst may be connected to the drain of the first transistor T1 and the source of the third transistor T3.

The light-emitting diode LED may be connected between the fourth and fifth transistors T4 and T5 and a low potential voltage ELVSS and may emit light with luminance proportional to a current of the driving transistor DT. The first electrode of the light-emitting diode LED, which is an anode, may be connected to the drain of the fourth transistor T4 and the drain of the fifth transistor T5. The second electrode of the light-emitting diode LED, which is a cathode, may be connected to the low potential voltage ELVSS.

In the embodiment of the present disclosure of FIG. 1, as an example, each sub-pixel has a 6TIC structure including six transistors and one capacitor, but in other embodiments, each sub-pixel may have one of 2TIC, 4TIC, 5TIC, 3T2C, 4T2C, 5T2C, 6T2C, 7TIC, 7T2C, 8TIC, and 8T2C structures.

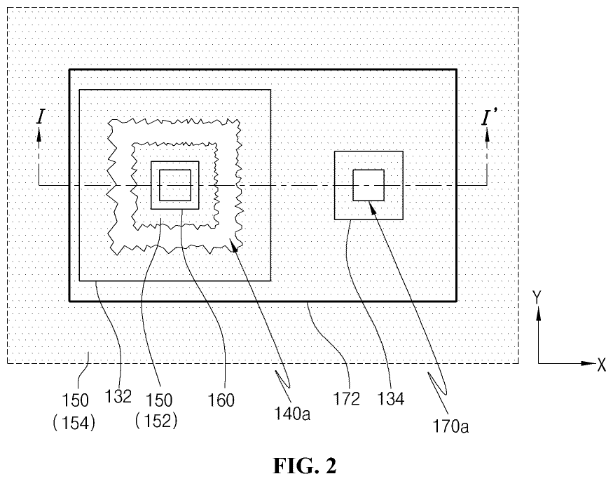

A planar configuration of a light-emitting diode display device according to the embodiment of the present disclosure having the above circuit configuration will be described with reference to FIG. 2.

FIG. 2 is a schematic plan view of a light-emitting diode display device according to the embodiment of the present disclosure and shows one sub-pixel.

In FIG. 2, one sub-pixel of the light-emitting diode display device according to the embodiment of the present disclosure may include a light-emitting element 160, a first electrode 132, and a second electrode 172. The light-emitting element 160 may overlap the first electrode 132 and the second electrode 172 and may be electrically connected to the first electrode 132 and the second electrode 172.

Specifically, the first electrode 132 and a connection electrode 134 may be disposed to be spaced apart from each other in a first direction X.

Next, an adhesive layer 150 may be disposed to overlap the first electrode 132 and the connection electrode 134. The adhesive layer 150 may include a first portion 152 and a second portion 154, and the first portion 152 may be disposed in the second portion 154.

In this case, the second portion 154 may have a hole corresponding to an opening 140a of a bank layer. The first portion 152 may be disposed in the hole of the second portion 154, and may be substantially spaced apart from the second portion 154 in the first direction X and a second direction Y.

A plurality of unevenness may be provided at side surfaces of the first portion 152 and the second portion 154, and the plurality of unevenness may be randomly provided without any regularity.

The first electrode 132 may overlap the first portion 152 and the second portion 154 of the adhesive layer 150. The connection electrode 134 may overlap the second portion 154 and may be spaced apart from the first portion 152. Meanwhile, a contact hole 170a may be provided to overlap the connection electrode 134.

Next, the light-emitting element 160 may be provided to overlap the first portion 152 of the adhesive layer 150. The light-emitting element 160 may be spaced apart from the second portion 154 of the adhesive layer 150. The light-emitting element 160 may overlap the first electrode 132 and may be electrically connected to the first electrode 132 through the first portion 152 of the adhesive layer 150.

Meanwhile, the second electrode 172 may be provided to overlap the light-emitting element 160 and the connection electrode 134. The second electrode 172 may overlap the first electrode 132 and also overlap the first portion 152 and the second portion 154 of the adhesive layer 150. The second electrode 172 may be electrically connected to the light-emitting element 160 and may be electrically connected to the connection electrode 134 through the contact hole 170a.

A cross-sectional structure of a light-emitting diode display device according to the embodiment of the present disclosure having the above planar configuration will be described with reference to accompanying drawings.

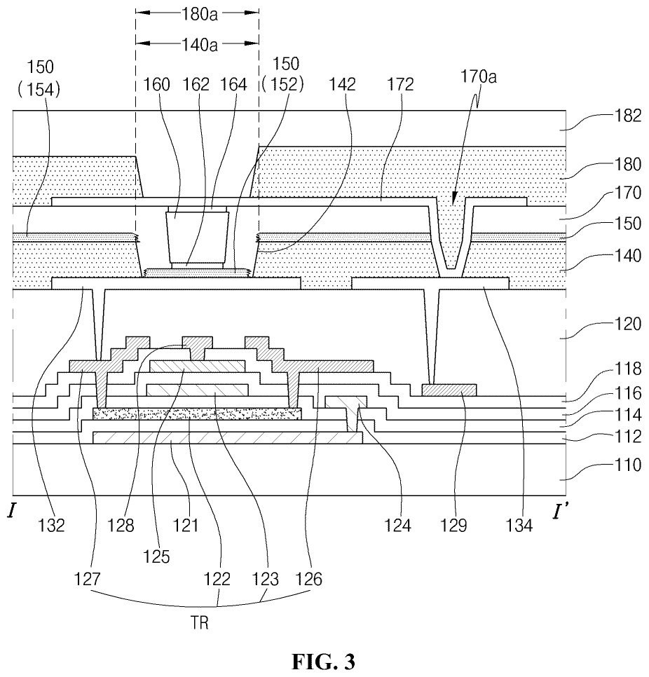

FIG. 3 is a schematic cross-sectional view of a light-emitting diode display device according to a first embodiment of the present disclosure. FIG. 3 shows a cross-section corresponding to line I-I′ of FIG. 2 and will be described with reference to FIGS. 1 and 2 together.

In FIG. 3, the light-emitting diode display device according to the first embodiment of the present disclosure may include a substrate (sometimes also referred to as “a first substrate”) 110, a thin film transistor TR, and a light-emitting element 160.

Specifically, a light-blocking layer 121 may be provided on the substrate 110. The substrate 110 may be formed of an insulating material and may be a glass substrate or a plastic substrate. For example, polyimide (PI) may be used for the plastic substrate, but embodiments of the present disclosure are not limited thereto.

The light-blocking layer 121 may be formed of a conductive material such as metal. For example, the light-blocking layer 121 may be formed of at least one of aluminum (Al), copper (Cu), molybdenum (Mo), titanium (Ti), chromium (Cr), nickel (Ni), tungsten (W), or an alloy thereof. The light-blocking layer 121 may have a single-layered structure or a multiple-layered structure.

Meanwhile, an insulation layer of an inorganic insulating material may be further provided between the substrate 110 and the light-blocking layer 121.

A buffer layer 112, which is a first insulation layer, may be provided on the light-blocking layer 121. The buffer layer 112 may be formed as a single layer or multiple layers of an inorganic insulating material. The inorganic insulating material of the buffer layer 112 may include silicon nitride (SiNx), silicon oxide (SiOx), or silicon oxynitride (SiON).

A semiconductor layer 122 may be provided on the buffer layer 112. The semiconductor layer 122 may overlap the light-blocking layer 121, and the light-blocking layer 121 may block light incident on the semiconductor layer 122 and prevent or reduce the semiconductor layer 122 from deteriorating due to the light.

The semiconductor layer 122 may include a channel region at its central part and source and drain regions at both sides of the channel region.

The semiconductor layer 122 may be formed of an oxide semiconductor material. Alternatively, the semiconductor layer 122 may be formed of polycrystalline silicon, and in this case, both end portions of the semiconductor layer 122 may be doped with impurities.

A gate insulation layer 114, which is a second insulation layer, may be provided on the semiconductor layer 122. The gate insulation layer 114 may be formed as a single layer or multiple layers of an inorganic insulating material. The inorganic insulating material of the gate insulation layer 114 may include silicon nitride (SiNx), silicon oxide (SiOx), or silicon oxynitride (SiON).

A gate electrode 123 and an auxiliary electrode 124 may be provided on the gate insulation layer 114.

The gate electrode 123 may overlap the semiconductor layer 122 and may be disposed to correspond to the central part of the semiconductor layer 122. Accordingly, the gate electrode 123 may also overlap the light-blocking layer 121.

The auxiliary electrode 124 may be spaced apart from the semiconductor layer 122 and may overlap the light-blocking layer 121. The auxiliary electrode 124 may be in contact with the light-blocking layer 121 through a contact hole provided in the buffer layer 112 and the gate insulation layer 114.

The gate electrode 123 and the auxiliary electrode 124 may be formed of a conductive material such as metal. For example, the gate electrode 123 and the auxiliary electrode 124 may be formed of at least one of aluminum (Al), copper (Cu), molybdenum (Mo), titanium (Ti), chromium (Cr), nickel (Ni), tungsten (W), or an alloy thereof. The gate electrode 123 and the auxiliary electrode 124 may have a single-layered structure or a multiple-layered structure.

A first interlayer insulation layer 116, which is a third insulation layer, may be provided on the gate electrode 123 and the auxiliary electrode 124. The first interlayer insulation layer 116 may be formed as a single layer or multiple layers of an inorganic insulating material. The inorganic insulating material of the first interlayer insulation layer 116 may include silicon nitride (SiNx), silicon oxide (SiOx), or silicon oxynitride (SiON).

A signal line 125 may be provided on the first interlayer insulation layer 116. The signal line 125 may overlap the gate electrode 123. Accordingly, the signal line 125 may also overlap the semiconductor layer 122 and the light-blocking layer 121.

A direct current voltage may be applied to the signal line 125. For example, a data voltage Vdata, a high potential voltage ELVDD, or a low potential voltage ELVSS may be applied to the signal line 125.

The signal line 125 may be formed of a conductive material such as metal. For example, the signal line 125 may be formed of at least one of aluminum (Al), copper (Cu), molybdenum (Mo), titanium (Ti), chromium (Cr), nickel (Ni), tungsten (W), or an alloy thereof. The signal line 125 may have a single-layered structure or a multiple-layered structure.

A second interlayer insulation layer 118, which is a fourth insulation layer, may be provided on the signal line 125. The second interlayer insulation layer 118 may be formed as a single layer or multiple layers of an inorganic insulating material. The inorganic insulating material of the second interlayer insulation layer 118 may include silicon nitride (SiNx), silicon oxide (SiOx), or silicon oxynitride (SiON).

A source electrode 126, a drain electrode 127, an auxiliary line 128, and a power line 129 may be provided on the second interlayer insulation layer 118.

The source electrode 126 and the drain electrode 127 may be spaced apart from each other with the gate electrode 123 positioned therebetween and may be in contact with both end portions of the semiconductor layer 122 through contact holes provided in the first and second interlayer insulation layers 116 and 118 and the gate insulation layer 114.

The semiconductor layer 122, the gate electrode 123, the source electrode 126, and the drain electrode 127 may constitute a thin film transistor TR.

The auxiliary line 128 may be spaced apart from the source electrode 126 and the drain electrode 127. The auxiliary line 128 may overlap the signal line 125 and may be in contact with the signal line 125 through a contact hole provided in the second interlayer insulation layer 118. The auxiliary line 128 may also overlap the gate electrode 123, the semiconductor layer 122, and the light-blocking layer 121.

The power line 129 may be spaced apart from the thin film transistor TR and the auxiliary line 128. For example, the power line 129 may be a line supplying the lower potential voltage ELVSS.

The source electrode 126, the drain electrode 127, the auxiliary line 128, and the power line 129 may be formed of a conductive material such as metal. For example, the source electrode 126, the drain electrode 127, the auxiliary line 128, and the power line 129 may be formed of at least one of aluminum (Al), copper (Cu), molybdenum (Mo), titanium (Ti), chromium (Cr), nickel (Ni), tungsten (W), or an alloy thereof. The source electrode 126, the drain electrode 127, the auxiliary line 128, and the power line 129 may have a single-layered structure or a multiple-layered structure.

A passivation layer 120, which is a fifth insulation layer, may be provided on the source electrode 126, the drain electrode 127, the auxiliary line 128, and the power line 129. The passivation layer 120 may be a planarization layer to eliminate a step difference due to the layers thereunder and may have a substantially flat top surface. The passivation layer 120 may be formed of an organic insulating material such as photosensitive acrylic polymer (photo acryl).

Meanwhile, an insulation layer, which is formed as a single layer or multiple layers of an inorganic insulating material, may be further provided under the passivation layer 120.

A first electrode 132 and a connection electrode 134 may be provided on the passivation layer 120. The first electrode 132 may overlap the drain electrode 127 and may be in contact with the drain electrode 127 through a contact hole provided in the passivation layer 120. The first electrode 132 may overlap the thin film transistor TR.

The connection electrode 134 may be spaced apart from the first electrode 132. The connection electrode 134 may overlap the power line 129 and may be in contact with the power line 129 through a contact hole provided in the passivation layer 120.

The first electrode 132 and the connection electrode 134 may be formed of a transparent conductive material and/or a conductive material such as metal. For example, the first electrode 132 and the connection electrode 134 may be formed of indium tin oxide (ITO) or indium zinc oxide (IZO) or may be formed of at least one of aluminum (Al), silver (Ag), copper (Cu), molybdenum (Mo), titanium (Ti), chromium (Cr), nickel (Ni), tungsten (W), or an alloy thereof. The first electrode 132 and the connection electrode 134 may have a single-layered structure or a multiple-layered structure.

A first bank layer 140 may be provided on the first electrode 132 and the connection electrode 134. The first bank layer 140 may overlap and cover edges of the first electrode 132 and may have a first opening 140a exposing a top surface of a central portion of the first electrode 132.

A side surface 142 of the first bank layer 140 corresponding to the first opening 140a may have a normal inclination. That is, the side surface 142 of the first bank layer 140 may have an inclination angle smaller than 90 degrees with respect to the substrate 110. Therefore, a width of the first opening 140a may increase as a distance from the first electrode 132 increases, and a top width of the first opening 140a may be greater than a bottom width of the first opening 140a.

In addition, the first bank layer 140 may cover the connection electrode 134 and expose a part of the connection electrode 134.

The first bank layer 140 may be formed as a single layer or multiple layers of an organic insulating material. For example, the first bank layer 140 may be formed of polyimide, photosensitive acrylic polymer (photo acryl), or benzocyclobutene (BCB).

Alternatively, the first bank layer 140 may include black particles absorbing and/or reflecting light, thereby increasing the efficiency of light emitted from the light-emitting element 160. For example, the black particles may include black pigments and/or carbon black provided in a resin. However, embodiments of the present disclosure are not limited thereto.

An adhesive layer 150 may be provided on the first bank layer 140 and the first electrode 132. The adhesive layer 150 may be an anisotropic conductive film (ACF) including an insulating base member and a plurality of conductive balls dispersed in the insulating base member. When heat and/or pressure is applied to the adhesive layer 150, in an area where the heat or pressure is applied, the conductive balls may be electrically connected, so that the adhesive layer 150 may have a conductive property, and in an area where the heat or pressure is not applied, the adhesive layer 150 may have an insulating property.

The adhesive layer 150 may include a first portion 152 and a second portion 154. The first portion 152 may be disposed on the top surface of the first electrode 132 exposed through the first opening 140a, and the second portion 154 may be disposed on a top surface of the first bank layer 140.

The first portion 152 and the second portion 154 of the adhesive layer 150 may not be connected to each other and may be separated from each other. A plurality of unevenness may be provided at side surfaces of the first portion 152 and the second portion 154, and the plurality of unevenness may be randomly provided without any regularity.

In addition, the second portion 154 of the adhesive layer 150 may be partially removed to thereby expose the part of the connection electrode 134, and the first portion 152 of the adhesive layer 150 may be disposed on the top surface of the first electrode 132 to thereby partially expose the first electrode 132.

The light-emitting element 160 may be provided on the adhesive layer 150. The light-emitting element 160 may be disposed on the first portion 152 of the adhesive layer 150 and may be located in the first opening 140a. The light-emitting element 160 may overlap the first electrode 132 and may be electrically connected to the first electrode 132 through the adhesive layer 150.

The light-emitting element 160 may include a first element electrode 162 and a second element electrode 164. Here, the first element electrode 162 may be a p-electrode, and the second element electrode 164 may be an n-electrode. The first element electrode 162 may be an anode, and the second element electrode 164 may be a cathode. However, embodiments of the present disclosure are not limited thereto.

Alternatively, in other embodiments, the first element electrode 162 may be an n-electrode, and the second element electrode 164 may be a p-electrode. In this case, the first element electrode 162 may be a cathode, and the second element electrode 164 may be an anode.

The light-emitting element 160 may be provided in the form of a micro light-emitting diode chip (micro LED chip or uLED chip) including the n-electrode, an n-type layer, an active layer, a p-type layer, and the p-electrode. The light-emitting element 160 may have a vertical structure in which the n-electrode and the p-electrode are provided on opposite sides (for example, a first side facing the substrate 110 and a second side opposite to the first side), respectively.

However, embodiments of the present disclosure are not limited thereto. The light-emitting element 160 may have a flip-chip structure in which the n-electrode and the p-electrode are provided on the same side (for example, the first side facing the substrate 110) and light is emitted through the second side opposite to the first side provided with the n-electrode and the p-electrode. Alternatively, the light-emitting element 160 may have a lateral structure in which the n-electrode and the p-electrode are provided on the same side and light is emitted through the same side provided with the n-electrode and the p-electrode.

The first element electrode 162 of the light-emitting element 160 may be disposed between the adhesive layer 150 and the second element electrode 164 and may be in contact with the adhesive layer 150. The first element electrode 162 may be electrically connected to the first electrode 132 through the adhesive layer 150.

In addition, a first protection layer 170 may be provided on the adhesive layer 150. The first protection layer 170 may be a planarization layer and may have a substantially flat top surface. The first protection layer 170 may eliminate a step difference due to the light-emitting element 160, and a top surface of the first protection layer 170 may be substantially flush with a top surface of the light-emitting element 160. That is, the top surface of the first protection layer 170 may be substantially flush with a top surface of the second element electrode 164.

The first protection layer 170 may have a contact hole 170a corresponding to the connection electrode 134 and exposing the part of the connection electrode 134. The contact hole 170a may be provided in the adhesive layer 150 and the first bank layer 140.

The first protection layer 170 may be formed of an organic insulating material such as photosensitive acrylic polymer (photo acryl).

A second electrode 172 may be provided on the first protection layer 170 and the light-emitting element 160. The second electrode 172 may be in contact with the second element electrode 164 of the light-emitting element 160 and may be electrically connected to the second element electrode 164. The second electrode 172 may overlap the first electrode 132 and the thin film transistor TR.

For example, the second electrode 172 may be formed of aluminum (Al), magnesium (Mg), silver (Ag), or an alloy thereof. In this case, the second electrode 172 may have a relatively thin thickness such that light from the light-emitting element 160 can be transmitted therethrough. Alternatively, in other embodiments, the second electrode 172 may be formed of a transparent conductive material such as indium gallium oxide (IGO) or IZO.

In addition, the second electrode 172 may overlap the connection electrode 134 and may be in contact with the connection electrode 134 through the contact hole 170a. The second electrode 172 may be electrically connected to the power line 129 through the connection electrode 134.

The second electrode 172 may be separated for each sub-pixel. However, embodiments of the present disclosure are not limited thereto. In other embodiments, the second electrodes 172 of adjacent sub-pixels may be connected to each other and provided as one body.

A second bank layer 180 may be provided on the second electrode 172 and the first protection layer 170. The second bank layer 180 may have a second opening 180a corresponding to the first opening 140a and exposing the second electrode 172.

The second bank layer 180 may be formed as a single layer or multiple layers of an organic insulating material. For example, the second bank layer 180 may be formed of polyimide, photosensitive acrylic polymer (photo acryl), or benzocyclobutene (BCB).

Alternatively, the second bank layer 180 may include black particles absorbing and/or reflecting light. For example, the black particles may include black pigments and/or carbon black provided in a resin. However, embodiments of the present disclosure are not limited thereto.

A second protection layer 182 may be provided on the second bank layer 180. The second protection layer 182 may be a planarization layer to eliminate a step difference due to the second opening 180a of the second bank layer 180 and may have a substantially flat top surface.

The second protection layer 182 may be formed of an organic insulating material such as photosensitive acrylic polymer (photo acryl).

In the light-emitting diode display device according to the first embodiment of the present disclosure, the first bank layer 140 may be provided between the first electrode 132 and the adhesive layer 150, thereby forming a gap between the first electrode 132 and the adhesive layer 150, and by directly transferring the light-emitting element 160 on the element substrate onto the adhesive layer 150, the first portion 152 of the adhesive layer 150 may be separated from the second portion 154 and may be disposed on the first electrode 132 together with the light-emitting element 160. Accordingly, it is possible to minimize impacts on the light-emitting element 160 and prevent the transfer failure.

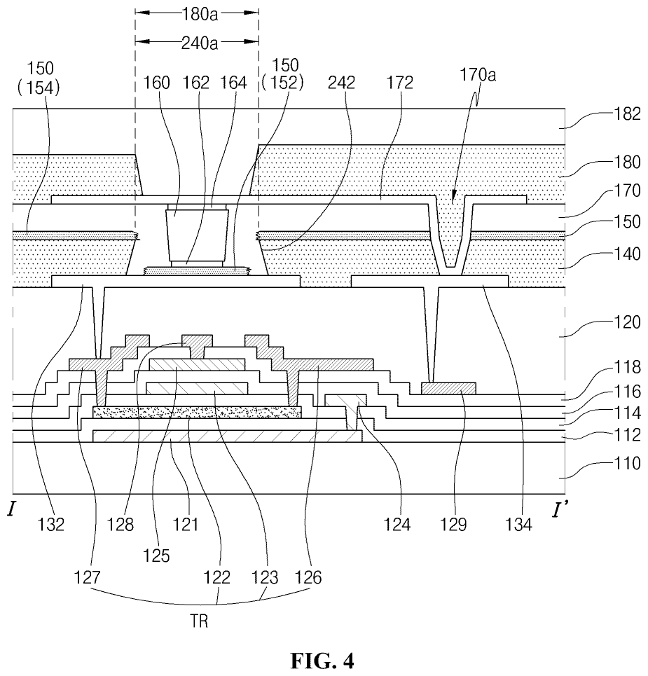

At this time, to easily separate the first portion 152 of the adhesive layer 150 from the second portion 154, the side surface 142 of the first bank layer 140 may have a reverse inclination. A light-emitting diode display device according to a second embodiment of the present disclosure having such a structure will be described with reference to FIG. 4.

FIG. 4 is a schematic cross-sectional view of a light-emitting diode display device according to a second embodiment of the present disclosure and shows a cross-section corresponding to line I-I′ of FIG. 2. The light-emitting diode display device according to the second embodiment of the present disclosure has substantially the same configuration as that of the first embodiment, except for the first bank layer. The same parts as those of the first embodiment are designated by the same reference signs, and explanation for the same parts may be shortened or omitted.

In FIG. 4, the first electrode 132 may be provided on the substrate 110 and may be connected to the thin film transistor TR. The first bank layer 140 may be provided on the first electrode 132 and may have the first opening 240a exposing the first electrode 132.

The side surface 242 of the first bank layer 140 corresponding to the first opening 240a may have a reverse inclination. That is, the side surface 242 of the first bank layer 140 may have an inclination angle greater than 90 degrees with respect to the substrate 110.

Therefore, the width of the first opening 240a may decrease as a distance from the first electrode 132 increases, and the top width of the first opening 240a may be smaller than the bottom width of the first opening 240a.

As such, in the light-emitting diode display device according to the second embodiment of the present disclosure, the side surface 242 of the first bank layer 140 may be configured to have the reverse inclination, and the thickness of the first bank layer 140 corresponding to the top of the first opening 240a may be made thin, so that the adhesive layer 150 provided on the first bank layer 140 can be easily separated into the first portion 152 and the second portion 154.

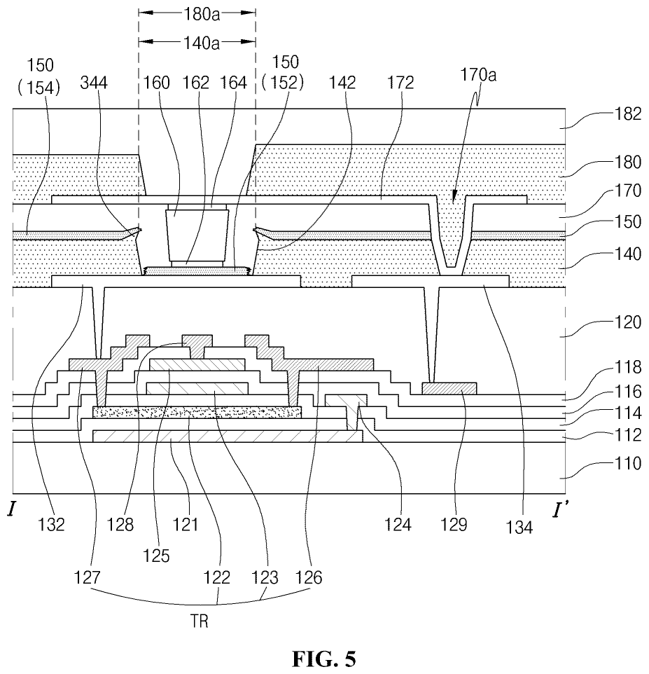

Meanwhile, to easily separate the first portion 152 of the adhesive layer 150 from the second portion 154, the first bank layer 140 may have a protrusion. A light-emitting diode display device according to a third embodiment of the present disclosure having such a structure will be described with reference to FIG. 5.

FIG. 5 is a schematic cross-sectional view of a light-emitting diode display device according to a third embodiment of the present disclosure and shows a cross-section corresponding to line I-I′ of FIG. 2. The light-emitting diode display device according to the third embodiment of the present disclosure has substantially the same configuration as that of the first embodiment, except for the first bank layer. The same parts as those of the first embodiment are designated by the same reference signs, and explanation for the same parts may be shortened or omitted.

In FIG. 5, the first electrode 132 may be provided on the substrate 110 and may be connected to the thin film transistor TR. The first bank layer 140 may be provided on the first electrode 132 and may have the first opening 140a exposing the first electrode 132.

The side surface 142 of the first bank layer 140 corresponding to the first opening 140a may have a substantially normal inclination. That is, the side surface 142 of the first bank layer 140 may have an inclination angle smaller than 90 degrees with respect to the substrate 110.

In addition, the first bank layer 140 may have a protrusion 344 corresponding to the first opening 140a. The protrusion 344 may protrude upward from the top surface of the first bank layer 140 corresponding to the first opening 140a, and a width of the protrusion 344 may decrease as a distance from the top surface of the first bank layer 140 increases.

In this case, a distance between facing portions of the protrusion 344 may decrease as the distance from the first electrode 132 increases.

Accordingly, the width of the first opening 140a may increase as the distance from the first electrode 132 increases, and then, in an area corresponding to the protrusion 344, the width of the first opening 140a may decrease as the distance from the first electrode 132 increases.

As such, in the light-emitting diode display device according to the third embodiment of the present disclosure, by providing the protrusion 344 on the top surface of the first bank layer 140 corresponding to the first opening 140a, the adhesive layer 150 provided on the first bank layer 140 can be easily divided into the first portion 152 and the second portion 154.

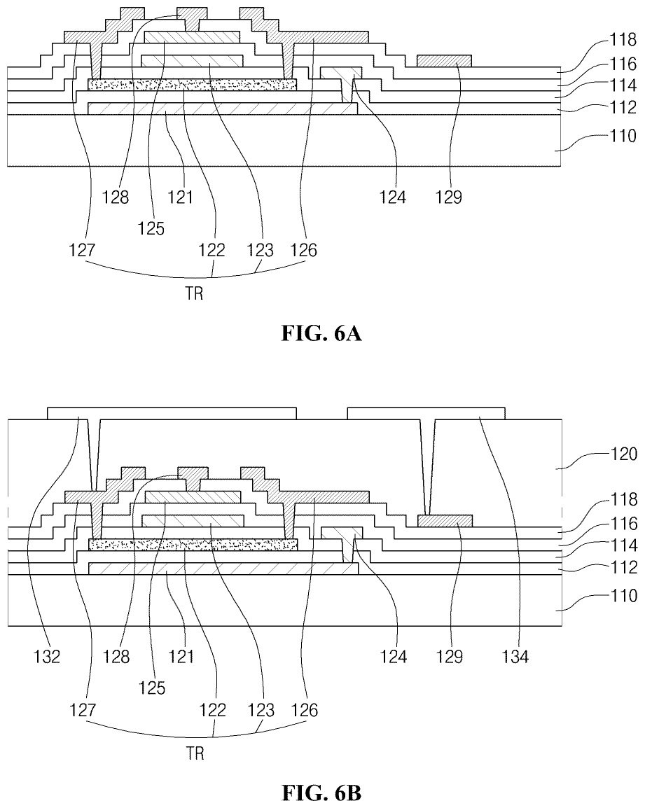

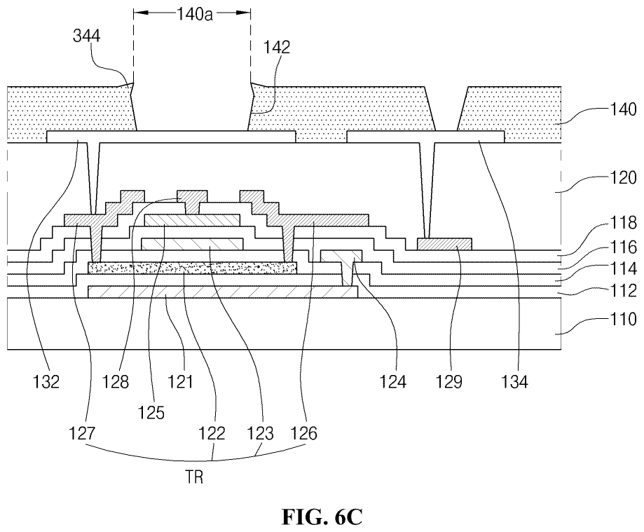

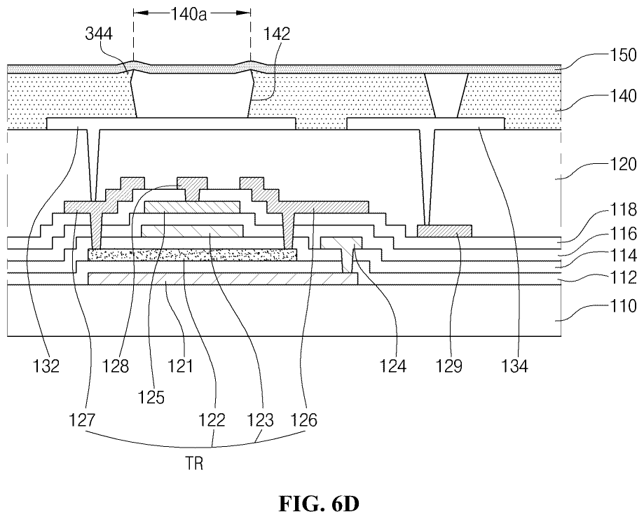

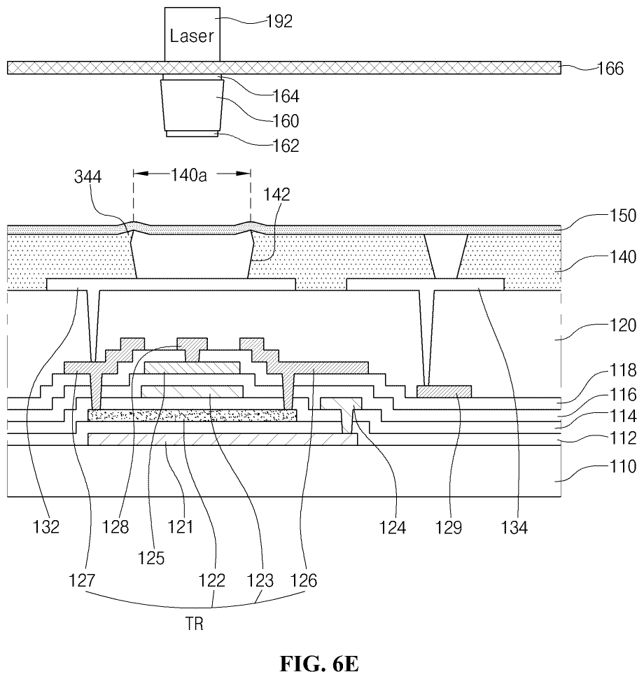

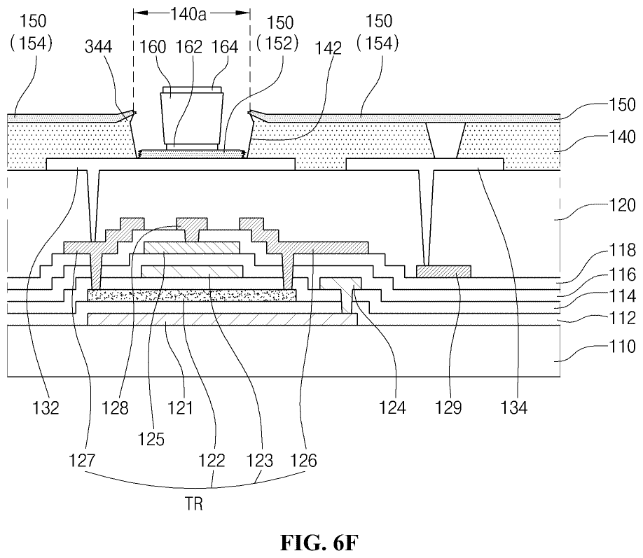

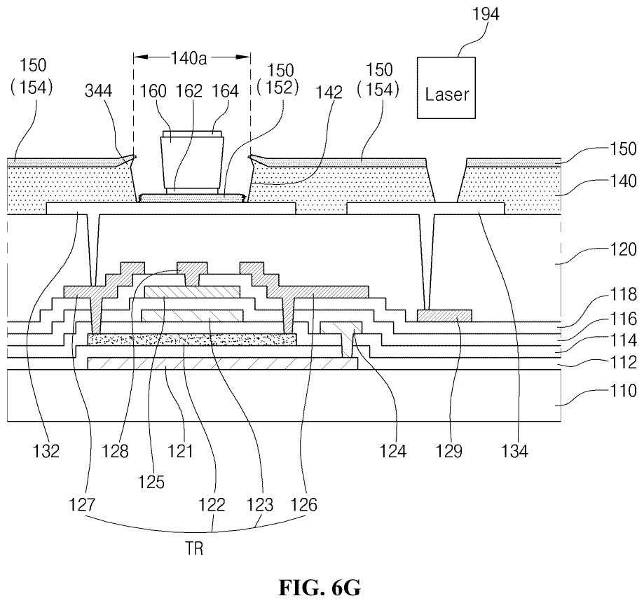

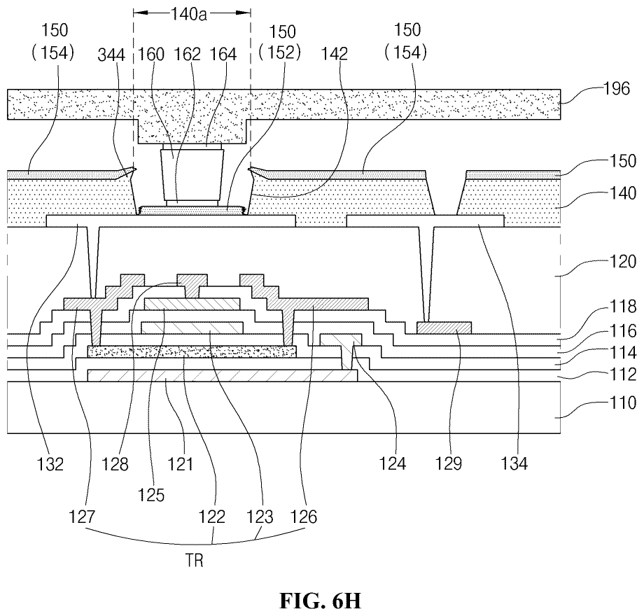

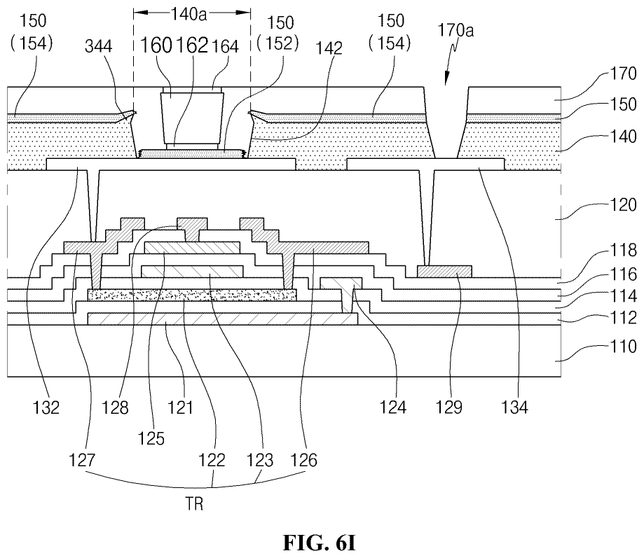

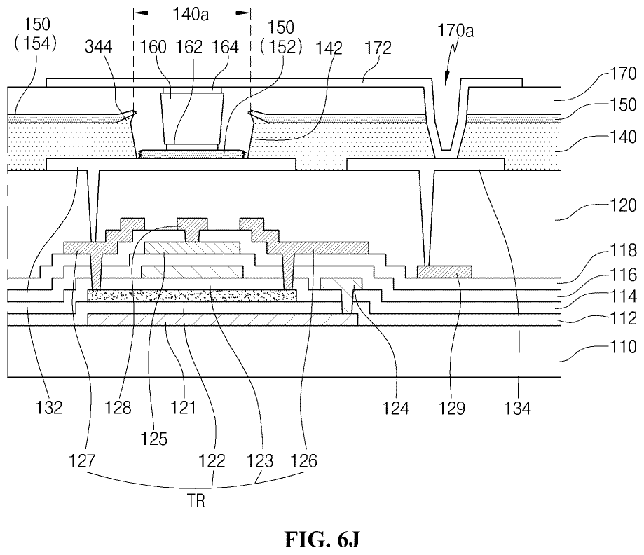

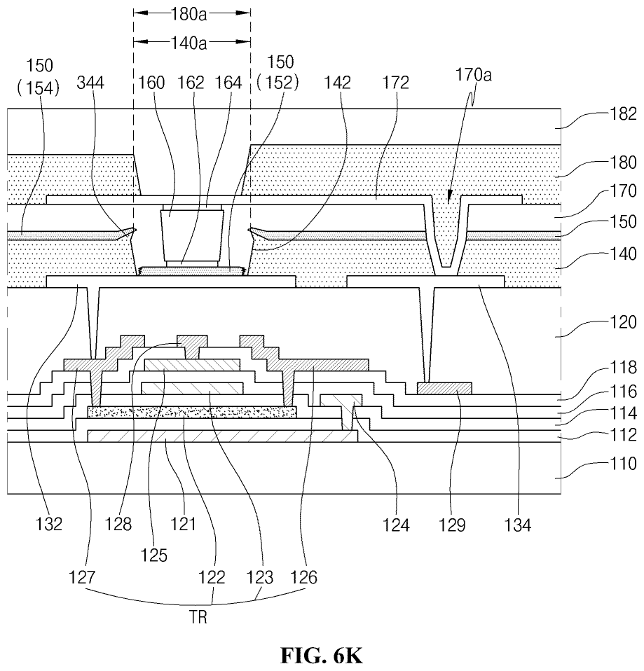

A method of manufacturing the light-emitting diode display device according to the third embodiment of the present disclosure will be described in detail with reference to FIGS. 6A to 6K.

FIGS. 6A to 6K are schematic cross-sectional views of a light-emitting diode display device in steps of manufacturing the same according to the third embodiment of the present disclosure, show cross-sections corresponding to line I-I′ of FIG. 2, and will be described with reference to FIG. 2 together.

In FIG. 6A, the light-blocking layer 121 may be formed on the substrate 110 by depositing a conductive material and patterning it through a photolithography process. The buffer layer 112 may be formed on the light-blocking layer 121 by depositing an inorganic insulating material over substantially the entire surface of the substrate 110. Then, the semiconductor layer 122 may be formed on the buffer layer 112 by depositing a semiconductor material and patterning it through a photolithography process. The semiconductor layer 122 may overlap the light-blocking layer 121.

Next, the gate insulation layer 114 may be formed on the semiconductor layer 122 by depositing an inorganic insulating material over substantially the entire surface of the substrate 110, and the gate insulation layer 114 and the buffer layer 112 may be selectively removed through a photolithography process, thereby forming the contact hole exposing the light-blocking layer 121.

Then, the gate electrode 123 and the auxiliary electrode 124 may be formed on the gate insulation layer 114 by depositing a conductive material and patterning it through a photolithography process. The gate electrode 123 may overlap the semiconductor layer 122, and the auxiliary electrode 124 may be in contact with the light-blocking layer 121 through the contact hole formed in the gate insulation layer 114 and the buffer layer 112.

Next, the first interlayer insulation layer 116 may be formed on the gate electrode 123, the auxiliary electrode 124, and the gate insulation layer 114 by depositing an inorganic insulating material. The signal line 125 may be formed on the first interlayer insulation layer 116 by depositing a conductive material and patterning it through a photolithography process. The signal line 125 may overlap the gate electrode 123.

Then, the second interlayer insulation layer 118 may be formed on the signal line 125 and the first interlayer insulation layer 116 by depositing an inorganic insulating material, and may be patterned through a photolithography process, thereby forming the contact hole exposing the signal line 125. In addition, the first interlayer insulation layer 116 and the gate insulation layer 114 may also be patterned together with the second interlayer insulation layer 118, thereby forming the contact holes exposing the semiconductor layer 122.

Next, the source electrode 126, the drain electrode 127, the auxiliary line 128, and the power line 129 may be formed on the second interlayer insulation layer 118 by depositing a conductive material and patterning it through a photolithography process.

The source electrode 126 and the drain electrode 127 may be spaced apart from each other with the gate electrode 123 positioned therebetween. The source electrode 126 and the drain electrode 127 may overlap the semiconductor layer 122 and may be in contact with both end portions of the semiconductor layer 122 through contact holes provided in the first and second interlayer insulation layers 116 and 118 and the gate insulation layer 114.

The semiconductor layer 122, the gate electrode 123, the source electrode 126, and the drain electrode 127 may constitute the thin film transistor TR.

The auxiliary line 128 may be disposed between the source electrode 126 and the drain electrode 127. The auxiliary line 128 may overlap the signal line 125 and may be in contact with the signal line 125 through the contact hole provided in the second interlayer insulation layer 118.

The power line 129 may be spaced apart from the thin film transistor TR and the auxiliary line 128.

Next, in FIG. 6B, the passivation layer 120 may be formed on the source electrode 126, the drain electrode 127, the auxiliary line 128, the power line 129, and the second interlayer insulation layer 118 by applying an organic insulating material, and may be patterned through a photolithography process, thereby forming the contact holes exposing the drain electrode 127 and the power line 129.

Then, the first electrode 132 and the connection electrode 134 may be formed on the passivation layer 120 by depositing a conductive material and patterning it through a photolithography process. The first electrode 132 may be in contact with the drain electrode 127 through the contact hole provided in the passivation layer 120, and the connection electrode 134 may be in contact with the power line 129 through the contact hole provided in the passivation layer 120.

Next, in FIG. 6C, the first bank layer 140 having the first opening 140a and the protrusion 344 may be formed on the first electrode 132 and the connection electrode 134 by applying an organic insulating material or a resin including black particles and patterning it through a photolithography process. The first opening 140a may expose the first electrode 132, and the protrusion 344 may be provided on the top end of the first opening 140a. Here, the side surface 142 of the first bank layer 140 corresponding to the first opening 140a may have a substantially normal inclination and may have an inclination angle smaller than 90 degrees with respect to the substrate 110.

Meanwhile, the contact hole exposing the connection electrode 134 may also be formed together with the first opening 140a.

Next, in FIG. 6D, the adhesive layer 150 may be formed on the first bank layer 140. For example, the adhesive layer 150 may be formed by laminating an anisotropic conductive film (ACF) in which a plurality of conductive balls is dispersed in an insulating base member.

In this case, the adhesive layer 150 may be spaced apart from the first electrode 132, thereby providing a gap between the adhesive layer 150 and the first electrode 132. In addition, the adhesive layer 150 may protrude convexly along the shape of the protrusion 344.

Next, in FIG. 6E, the element substrate 166 provided with the light-emitting element 160 may be disposed over and spaced apart from the adhesive layer 150. In this case, a surface of the element substrate 166 on which the light-emitting element 160 is provided may face the adhesive layer 150. For example, a distance between the adhesive layer 150 and the element substrate 166 may be 50 μm to 100 μm.

Meanwhile, a distance between the adhesive layer 150 and the first electrode 132 may be smaller than the distance between the adhesive layer 150 and the element substrate 166. For example, the distance between the adhesive layer 150 and the first electrode 132 may be several μm.

Then, the light-emitting element 160 may be detached from the element substrate 166 by irradiating the laser beam 192 from the upper part of the element substrate 166.

Next, in FIG. 6F, the light-emitting element 160 separated from the element substrate 166 may be in contact with the adhesive layer 150 on the first electrode 132, and the adhesive layer 150 may be divided into the first portion 152 on the first electrode 132 and the second portion 154 on the first bank layer 140 by the light-emitting element 160, so that the first portion 152 separated from the second portion 154 can be transferred onto the first electrode 132 together with the light-emitting element 160.

In this case, since the impact on the light-emitting element 160 is mitigated by the gap between the adhesive layer 150 and the first electrode 132, the light-emitting element 160 can be placed on the first electrode 132 without damages.

Here, the first element electrode 162 of the light-emitting element 160 may be in contact with the first portion 152 of the adhesive layer 150.

Next, in FIG. 6G, the adhesive layer 150 may be partially removed to correspond to the connection electrode 134 by irradiating the laser beam 194 to the substrate 110 on which the light-emitting element 160 is transferred.

Next, in FIG. 6H, the mechanism 196 may be disposed over the light-emitting element 160, and heat and pressure may be applied to the light-emitting element 160. Accordingly, the first element electrode 162 of the light-emitting element 160 may be electrically connected to the first electrode 132 through the first portion 152 of the adhesive layer 150.

Next, in FIG. 6I, the first protection layer 170 may be formed on the light-emitting element 160 and the adhesive layer 150 by applying an organic insulation material and then may be patterned through a photolithography process, thereby forming the contact hole 170a exposing the connection electrode 134. The contact hole 170a may also be provided in the adhesive layer 150 and the first bank layer 140.

Here, the top surface of the first protection layer 170 may be substantially flush with the top surface of the light-emitting element 160.

Next, in FIG. 6J, the second electrode 172 may be formed on the first protection layer 170 by depositing a conductive material and patterning it through a photolithography process. The second electrode 172 may be in contact with the second element electrode 164 of the light-emitting element 160. The second electrode 172 may also be in contact with the connection electrode 134 through the contact hole 170a of the first protection layer 170 and may be electrically connected to the power line 129 through the connection electrode 134.

Next, in FIG. 6K, the second bank layer 180 having the second opening 180a may be formed on the second electrode 172 by applying an organic insulating material or a resin including black particles and patterning it through a photolithography process. The second opening 180a may expose the second electrode 172 corresponding to the first opening 140a.

Then, the second protection layer 182 may be formed on the second bank layer 180 by applying an organic insulation material.

As such, in the method of manufacturing the light-emitting diode display device according to the third embodiment of the present disclosure, the first bank layer 140 may be provided between the first electrode 132 and the adhesive layer 150, thereby forming the gap between the first electrode 132 and the adhesive layer 150. The light-emitting element 160 provided on the element substrate 166 may be directly transferred onto the substrate 110 on which the thin film transistor TR is provided through the adhesive layer 150, so that the manufacturing time and costs can be reduced by simplifying the transfer process and the transfer failure of the light-emitting element 160 can be prevented by mitigating the impact on the light-emitting element 160.

In this case, by providing the protrusion 344 to the first bank layer 140, the first portion 152 of the adhesive layer 150 contacting the light-emitting element 160 can be easily separated from the second portion 154 of the adhesive layer 150 on the first bank layer 140.

Meanwhile, the steps of manufacturing the light-emitting diode display device according to the third embodiment of the present disclosure can be applied equally to the light-emitting diode display devices according to the first and second embodiments.

In the light-emitting diode display device of the present disclosure, by directly transferring the light-emitting element from the element substrate onto the substrate of the display device, the manufacturing process can be simplified, and thus the manufacturing time and costs can be reduced.

In addition, the impact on the light-emitting element can be mitigated, so that the transfer failure of the light-emitting element can be prevented.

Accordingly, the manufacturing process of the light-emitting diode display device can be optimized, thereby reducing the production energy.

It will be apparent to those skilled in the art that various modifications and variations can be made in the light-emitting diode display device and the method of manufacturing the same of the present disclosure without departing from the technical idea or scope of the disclosure. Thus, it is intended that the present disclosure cover the modifications and variations of this disclosure provided they come within the scope of the appended claims and their equivalents.

What is claimed is:

1. A light-emitting diode display device, comprising:
a substrate;
a first electrode over the substrate;
a first bank layer on the first electrode and having a first opening exposing the first electrode;
an adhesive layer including a first portion on the first electrode exposed through the first opening; and
a light-emitting element provided on the first portion of the adhesive layer,
wherein the first portion has a side surface provided with a plurality of unevenness.

2. The light-emitting diode display device of claim 1, wherein the adhesive layer further includes a second portion on the first bank layer, and
wherein the second portion is separated from the first portion, and has a side surface provided with a plurality of unevenness.

3. The light-emitting diode display device of claim 1, wherein the first bank layer has a protrusion protruding upward from a top surface of the first bank layer corresponding to the first opening.

4. The light-emitting diode display device of claim 3, wherein a width of the protrusion decreases as a distance from the top surface of the first bank layer increases.

5. The light-emitting diode display device of claim 1, wherein a width of the first opening decreases as a distance from the first electrode increases.

6. The light-emitting diode display device of claim 1, wherein a width of the first opening increases as a distance from the first electrode increases.

7. The light-emitting diode display device of claim 1, wherein the first bank layer includes black particles.

8. The light-emitting diode display device of any of claim 1, further comprising:
a power line provided between the substrate and the first bank layer; and
a second electrode on the light-emitting element and electrically connected to the power line.

9. The light-emitting diode display device of claim 8, wherein the light-emitting element includes a first element electrode electrically connected to the first electrode through the first portion and a second element electrode being in contact with the second electrode.

10. The light-emitting diode display device of claim 9, further comprising:
a first protection layer provided between the adhesive layer and the second electrode;
a second bank layer on the second electrode and having a second opening corresponding to the first opening; and
a second protection layer on the second bank layer.

11. A method of manufacturing a light-emitting diode display device, the method comprising:
forming a first electrode over a first substrate;
forming a first bank layer on the first electrode and having a first opening exposing the first electrode;
forming an adhesive layer on the first bank layer; and
transferring a light-emitting element on the adhesive layer corresponding to the first electrode,
wherein the adhesive layer includes a first portion between the first electrode and the light-emitting element and a second portion on the first bank layer, and
wherein the first portion is separated from the second portion, and the first portion and the second portion each has a side surface provided with a plurality of unevenness.

12. The method of claim 11, wherein forming the first bank layer includes forming a protrusion protruding upward from a top surface of the first bank layer corresponding to the first opening.

13. The method of claim 11, wherein transferring the light-emitting element includes:
disposing an element substrate provided with the light-emitting element to be spaced apart from the adhesive layer;
detaching the light-emitting element from the element substrate by irradiating a laser beam to the element substrate;
dividing the adhesive layer into the first portion and the second portion by attaching the light-emitting element detached from the element substrate to the adhesive layer, and
placing the first portion separated from the second portion on the first electrode.

14. The method of claim 13, further comprising:
forming a power line between the first substrate and the first bank layer; and
forming a second electrode on the light-emitting element, the second electrode being electrically connected to the power line.

15. The method of claim 14, further comprising:
forming a first protection layer between the adhesive layer and the second electrode;
forming a second bank layer on the second electrode, the second bank layer having a second opening corresponding to the first opening; and
forming a second protection layer on the second bank layer.
